(19) United States
(12) Patent Application Publication
(10) Pub. No.: US 2026/0313803 A1
(43) Pub. Date: Oct. 8, 2026

(54) ADHESIVE AND METHOD FOR MANUFACTURING CIRCUIT CONNECTION STRUCTURE

(71) Applicant: Resonac Corporation, Minato-ku, Tokyo (JP)

(72) Inventors: Mayumi SATO, Tokyo (JP); Takahiro FUKUI, Tokyo (JP); Hiroyuki IZAWA, Tokyo (JP); Katsuhiko TOMISAKA, Tokyo (JP)

(21) Appl. No.: 19/479,496

(22) PCT Filed: Sep. 10, 2024
(86) PCT No.: PCT/JP2024/032393

§ 371 Date: Oct. 28, 2025

(30) Foreign Application Priority Data
Sep. 11, 2023 (JP) 2023-146894

(51) Int. Cl. H05K 1/14; H05K 3/36

(52) U.S. Cl. CPC H05K 1/144; H05K 3/368; H05K 2201/041; H05K 2203/04

(57) ABSTRACT

An adhesive that is thermosetting and used in thermocompression bonding of a pair of circuit members via a solder connection material in a method for manufacturing a circuit connection structure including the pair of circuit members electrically connected by solder bonding, having a curing temperature Tc such that a difference (Tc−Tm) from a melting point Tm of the solder connection material is −20° C. or more, and a melt viscosity at the melting point Tm of the solder connection material of 5.0×10⁵ Pa·s or less.

### TECHNICAL FIELD

The present disclosure relates to an adhesive and a method for manufacturing a circuit connection structure.

### BACKGROUND ART

As a method for manufacturing a circuit connection structure such as a semiconductor device, a flip-chip mounting method is known in which a circuit member (such as a semiconductor chip) having solder bumps is directly mounted on another circuit member (such as a wiring circuit substrate) via the solder bumps. In this method, electrodes of the circuit members facing each other are electrically connected by solder bonding.

In the flip-chip mounting method, an underfill that fills a gap between the circuit members and seals connection portions is formed of an adhesive. As the adhesive for forming the underfill, for example, a thermosetting adhesive is used (see, for example, Patent literature 1).

As the adhesive for forming the underfill, an anisotropically conductive adhesive containing conductive particles such as solder particles has also attracted attention (see, for example, Patent literature 2). Here, “anisotropically conductive” means that conduction occurs in the pressurizing direction while insulation is maintained in the non-pressurizing direction. According to the anisotropically conductive adhesive, without previously forming solder bumps, electrodes of opposing circuit members (opposing electrodes) can be connected through conductive particles interposed therebetween.

### CITATION LIST

### Patent Literature

Patent literature 1: Japanese Unexamined Patent Application Publication No. 2003-142529
Patent literature 2: Japanese Unexamined Patent Application Publication No. 2012-046756

### SUMMARY OF INVENTION

### Technical Problem

When a connection material containing solder (hereinafter referred to as “solder connection material”) is used as an electrode connection material, it has been confirmed that voids occur near solder connection portions of a circuit connection structure obtained by thermocompression bonding of circuit members. Such occurrence of voids is particularly conspicuous when a plurality of semiconductor chips are mounted collectively on a large-area circuit substrate.

One aspect of the present disclosure is to suppress the occurrence of voids near solder connection portions of a circuit connection structure.

### Solution to Problem

The present disclosure provides at least the following [1] to [11].

[1]

An adhesive that is thermosetting and used in thermocompression bonding of a pair of circuit members via a solder connection material in a method for manufacturing a circuit connection structure including the pair of circuit members electrically connected by solder bonding,
wherein the adhesive has
a curing temperature Tc such that a difference (Tc−Tm) from a melting point Tm of the solder connection material is −20° C. or more, and
a melt viscosity at the melting point Tm of the solder connection material of 5.0×10⁵ Pa·s or less.
   [2]

The adhesive according to [1], wherein the curing temperature Tc is 100° C. to 200° C.

[3]

The adhesive according to [1] or [2], having a melt viscosity at 157° C. of 5.0×10⁵ Pa·s or less.

[4]

The adhesive according to any one of [1] to [3], including at least a thermosetting resin and a curing agent for the thermosetting resin,

wherein the thermosetting resin includes an epoxy resin.

[5]

The adhesive according to [4], wherein the curing agent includes an imidazole-based curing agent.

[6]

The adhesive according to [4] or [5], wherein the curing agent includes a microencapsulated latent curing agent.

[7]

The adhesive according to any one of [1] to [6], wherein the adhesive is insulating.

[8]

The adhesive according to any one of [1] to [6], containing the solder connection material.

[9]

The adhesive according to any one of [1] to [8], wherein the adhesive is in the form of a film.

[10]

The adhesive according to any one of [1] to [9], wherein at least one of the pair of circuit members has an electrode including copper, gold, or a gold alloy on a surface in contact with the solder connection material, and

the solder connection material includes at least one selected from the group consisting of tin, tin alloys, indium, and indium alloys.

[11]

A method for manufacturing a circuit connection structure using a solder connection material, including:
a step (a) of arranging a pair of circuit members such that electrodes of the pair of circuit members face each other; and
a step (b) of thermocompression bonding the pair of circuit members arranged to face each other via a thermosetting adhesive,
wherein the solder connection material is disposed on the electrode of at least one of the pair of circuit members, or the adhesive contains the solder connection material,
a difference (Tc−Tm) between a curing temperature Tc of the adhesive and a melting point Tm of the solder connection material is −20° C. or more, and
a melt viscosity of the adhesive at the melting point Tm of the solder connection material is 5.0×10⁵ Pa·s or less.

### Advantageous Effects of Invention

According to one aspect of the present disclosure, the occurrence of voids near solder connection portions of a circuit connection structure can be suppressed.

### BRIEF DESCRIPTION OF DRAWINGS

FIG. 1 is a schematic cross-sectional view illustrating one embodiment of a method for manufacturing a circuit connection structure.

FIG. 2 is a schematic cross-sectional view illustrating another embodiment of a method for manufacturing a circuit connection structure.

### DESCRIPTION OF EMBODIMENTS

Unless otherwise specified, the materials exemplified in the present specification may be used alone as a single kind or in combination of two or more kinds. A numerical range indicated using “to” represents a range including the numerical values before and after “to” as minimum and maximum values, respectively. Unless specifically stated otherwise, the units of the numerical values before and after “to” are the same. In numerical ranges described stepwise in the present specification, the upper or lower limit value of a numerical range at one stage may be replaced with the upper or lower limit value of a numerical range at another stage. In a numerical range described in the present specification, the upper or lower limit value of the numerical range may be replaced with a value shown in Examples. The upper and lower limit values individually described may be arbitrarily combined.

Embodiments of the present disclosure will be described below. However, the present disclosure is not limited to these embodiments.

### <Adhesive>

One embodiment of the present disclosure relates to a thermosetting adhesive having a melt viscosity at a temperature Tx of 5.0×10⁵ Pa·s or less.

In the present specification, the melt viscosity of the adhesive is a value measured using a melt viscosity measuring apparatus under the conditions of measurement temperature: 0° C. to 200° C., temperature ramp rate: 10° C./min, frequency: 10 Hz, and strain: 1%.

The temperature Tx may be, for example, 100° C., and may also be 120° C., 130° C., or 140° C. The temperature Tx may also be, for example, 300° C., 200° C., 180° C., or 160° C.

The adhesive has a curing temperature Tc. In the present specification, the curing temperature Tc of the adhesive means a peak temperature of an exothermic peak with a maximum heat generation among the exothermic peaks observed in a differential scanning calorimetry (DSC) curve obtained when differential scanning calorimetry (DSC) measurement of the adhesive is performed using a differential scanning calorimeter under helium atmosphere (He gas flow) under the conditions of a temperature range of 40° C. to 300° C. and a temperature ramp rate of 10° C./min.

The curing temperature Tc is, for example, 100° C. to 200° C., preferably 105° C. to 195° C., and more preferably 110° C. to 185° C. The curing temperature Tc may be 120° C. or higher, 140° C. or higher, 160° C. or higher, or 180° C. or higher, and may be 120° C. to 185° C., 140° C. to 185° C., 160° C. to 185° C., or 180° C. to 185° C.

The transition initiation temperature (onset temperature) of an exothermic peak indicating the curing temperature Tc may be 90° C. to 200° C., and may also be 95° C. to 195° C. or 100° C. to 190° C.

The curing temperature Tc (and the onset temperature) of the adhesive can be adjusted, for example, by the types of a thermosetting resin and a curing agent contained in the adhesive (for example, by using a microencapsulated latent curing agent) and by their blending ratios.

The difference (Tc−Tx) between the curing temperature Tc and the temperature Tx is, for example, −20° C. or more, may also be −15° C. or more, −10° C. or more, 0° C. or more, 10° C. or more, or 20° C. or more, may also be 50° C. or less, 40° C. or less, or 30° C. or less, and may be −20° C. to 50° C., −15° C. to 40° C., −10° C. to 30° C., 0° C. to 30° C., 10° C. to 30° C., or 20° C. to 30° C.

The difference (Tc−Ty) between Tc and a temperature Ty at which the melt viscosity becomes 5.0×10⁵ Pa·s is, for example, −20° C. or more, may also be −15° C. or more or −10° C. or more, may also be 50° C. or less, 40° C. or less, or 30° C. or less, and may be −20° C. to 50° C., −15° C. to 40° C., or −10° C. to 30° C.

The adhesive is, for example, a thermosetting adhesive used in thermocompression bonding of a pair of circuit members via a solder connection material in a method for manufacturing a circuit connection structure including the pair of circuit members electrically connected by solder bonding.

The adhesive has, for example, a curing temperature Tc such that a difference (Tc−Tm) from a melting point Tm of the solder connection material is −20° C. or more, and has a melt viscosity at the melting point Tm of the solder connection material of 5.0×10⁵ Pa·s or less.

In the present specification, the melting point Tm of the solder connection material means a peak temperature of the lowest-temperature endothermic peak observed in a differential scanning calorimetry (DSC) curve obtained when differential scanning calorimetry (DSC) measurement of the solder connection material is performed using a differential scanning calorimeter under helium atmosphere (He gas flow) under the conditions of a temperature range of 40° C. to 300° C. and a temperature ramp rate of 10° C./min.

According to the adhesive described above, the occurrence of voids near solder connection portions of a circuit connection structure can be suppressed. The reason for this is presumed to be as follows. First, when a solder connection material is used for connecting circuit members together, after the solder connection material is melted by heating during thermocompression bonding, a phenomenon occurs in which a portion of the molten solder connection material diffuses into electrodes of the circuit members. At this time, if curing of the adhesive is in progress, a space (a portion where the solder connection material was present) produced by diffusion of the solder connection material is not filled by the adhesive, and voids are considered to occur. In contrast, since the adhesive described above has a curing temperature Tc such that a difference (Tc−Tm) from the melting point Tm of the solder connection material is −20° C. or more and has a melt viscosity of 5.0×10⁵ Pa·s or less at the melting point Tm of the solder connection material, the adhesive can sufficiently flow even at a temperature at which the solder connection material melts, and even if the solder connection material diffuses into the electrodes, the adhesive flows into the space produced by diffusion of the solder connection material. Therefore, it is presumed that, according to the adhesive described above, the occurrence of voids near solder connection portions of a circuit connection structure can be suppressed.

The adhesive, for example, contains at least a thermosetting resin (hereinafter also referred to as “component (A)”) and a curing agent for the thermosetting resin (hereinafter also referred to as “component (B)”). The adhesive may further contain a thermoplastic resin (hereinafter also referred to as “component (C)”), a non-conductive filler (hereinafter also referred to as “component (D)”), an organic acid component (hereinafter also referred to as “component (E)”), and the like.

The adhesive may be conductive (for example, anisotropically conductive) or insulating (non-conductive). Here, being conductive means that a conductive material is contained, and being insulating means that a conductive material is not contained. The conductive material may be any metal having conductivity, and examples include metals such as gold, silver, palladium, ruthenium, iridium, nickel, tungsten, molybdenum, copper, tin, and solder. The conductive material (for example, conductive particles) may be a solder connection material (for example, solder particles). That is, the adhesive may contain a solder connection material. Hereinafter, the solder connection material contained in the adhesive is referred to as “component (F)”, and among components contained in the adhesive, components other than the solder connection material are referred to as “adhesive components”.

### [Component (A): Thermosetting Resin]

Component (A) is not particularly limited as long as it cures to have an adhesive action, but from the viewpoint of obtaining the effect of the present disclosure (the effect of suppressing voids) more markedly, an epoxy resin may be used. As the epoxy resin, known epoxy resins (for example, epoxy resins described in “Epoxy Resin Handbook” (edited by Masaki Shinbo, Nikkan Kogyo Shimbun, Ltd., 1987)) can be used. Examples of component (A) include bifunctional epoxy resins such as bisphenol A type epoxy and bisphenol F type epoxy, novolac type epoxy resins such as phenol novolac type epoxy resins and cresol novolac type epoxy resins, and trisphenol methane type epoxy resins. Component (A) may be those generally known such as multifunctional epoxy resins, glycidyl amine type epoxy resins, heterocycle-containing epoxy resins, and alicyclic epoxy resins.

From the viewpoint of maintaining heat resistance and adhesiveness of the adhesive after curing and exhibiting high reliability, the content of component (A) is preferably 40 to 95 parts by mass, 50 to 90 parts by mass, 60 to 85 parts by mass, or 70 to 80 parts by mass per 100 parts by mass in total of component (A) and component (C) described later. When the content of component (A) is 40 parts by mass or more, there is a tendency that even higher connection reliability is easily obtained. When the content of component (A) is 95 parts by mass or less, there is a tendency that an adhesive layer easily maintains its form.

### [Component (B): Curing Agent]

Examples of component (B) include imidazole-based curing agents, phenolic resin-based curing agents, acid anhydride-based curing agents, amine-based curing agents, and phosphine-based curing agents. Among these, when an imidazole-based curing agent is used in combination with the epoxy resin (component (A)), there is a tendency that the effect of the present disclosure (the effect of suppressing voids) is obtained more markedly.

Examples of the imidazole-based curing agent include 2-phenylimidazole, 2-phenyl-4-methylimidazole, 1-benzyl-2-methylimidazole, 1-benzyl-2-phenylimidazole, 1-cyanoethyl-2-undecylimidazole, 1-cyano-2-phenylimidazole, 1-cyanoethyl-2-undecylimidazole trimellitate, 1-cyanoethyl-2-phenylimidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, 2,4-diamino-6-[2′-methylimidazolyl-(1′)]-ethyl-s-triazine isocyanurate adduct, 2-phenylimidazole isocyanurate adduct, 2-phenyl-4,5-dihydroxymethylimidazole, 2-phenyl-4-methyl-5-hydroxymethylimidazole, and adducts of epoxy resins and imidazoles. Among these, from the viewpoint of excellent curability, the imidazole-based curing agent may be 2,4-diamino-6-[2′-methylimidazolyl-(1′)]-ethyl-s-triazine isocyanurate adduct.

The content of the imidazole-based curing agent may be 0.1 to 40 parts by mass per 100 parts by mass of component (A). When the content of the imidazole-based curing agent is 0.1 parts by mass or more, there is a tendency that a sufficient curing reaction rate is easily obtained. When the content of the imidazole-based curing agent is 40 parts by mass or less, there is a tendency that good heat resistance and adhesiveness are easily maintained. The content of the imidazole-based curing agent may be 1 to 30 parts by mass, 3 to 20 parts by mass, or 5 to 10 parts by mass per 100 parts by mass of component (A).

Examples of the phenolic resin-based curing agent include various multifunctional phenolic resins such as phenol novolac resins, cresol novolac resins, phenol aralkyl resins, cresol-naphthol-formaldehyde polycondensates, and triphenylmethane-type multifunctional phenolic resins. The equivalent ratio of the phenolic resin-based curing agent to component (A) (phenolic hydroxyl groups of the phenolic resin-based curing agent/epoxy groups of component (A) (molar ratio)) may be 0.3 to 1.5, 0.4 to 1.0, or 0.5 to 1.0.

Examples of the acid anhydride-based curing agent include methylcyclohexane tetracarboxylic dianhydride, trimellitic anhydride, pyromellitic anhydride, benzophenone tetracarboxylic dianhydride, and ethylene glycol bis-anhydrotrimellitate. The equivalent ratio of the acid anhydride-based curing agent to component (A) (acid anhydride groups of the acid anhydride-based curing agent/epoxy groups of component (A) (molar ratio)) may be 0.3 to 1.5, 0.4 to 1.0, or 0.5 to 1.0.

Examples of the amine-based curing agent include dicyandiamide. The equivalent ratio of the amine-based curing agent to component (A) (amino groups of the amine-based curing agent/epoxy groups of component (A) (molar ratio)) may be 0.3 to 1.5, 0.4 to 1.0, or 0.5 to 1.0.

Examples of the phosphine-based curing agent include triphenylphosphine, tetraphenylphosphonium tetraphenylborate, tetraphenylphosphonium tetra(4-methylphenyl)borate, and tetraphenylphosphonium (4-fluorophenyl)borate. The content of the phosphine-based curing agent may be 0.1 to 10 parts by mass or 0.1 to 5 parts by mass per 100 parts by mass of component (A).

As component (B), a latent curing agent (microencapsulated latent curing agent) obtained by microencapsulating the above-described curing agent can also be used. By using a microencapsulated latent curing agent, adjustment of the reaction temperature (peak temperature of the exothermic peak) of the adhesive becomes easy. For example, the thicker the capsule membrane of the microencapsulated latent curing agent is, the higher the reaction temperature (peak temperature of the exothermic peak) of the adhesive tends to be, and the more difficult gelation tends to be (when the mounting temperature is fixed, gel time becomes long, and when the gel time is fixed, gelation temperature becomes high). The gel time at 100° C. in the case of the microencapsulated latent curing agent alone may be 1 minute or more (for example, 1 to 180 minutes), may be 2 minutes or more, and may also be 30 minutes or more. The more difficult gelation is, the more easily storage stability is improved. The microencapsulated latent curing agent may be, for example, a latent curing agent obtained by microencapsulating an imidazole-based curing agent.

The microencapsulated latent curing agent can be, for example, one commercially available as a mixture with a thermosetting resin. Examples of commercially available products containing a microencapsulated latent curing agent include “HX-3042HP”, “HXA4982HP”, and “HXA9382HP” (all manufactured by Asahi Kasei Corporation).

The content of component (B) may be 0.1 to 40 parts by mass per 100 parts by mass of component (A). When the content of component (B) is 0.1 parts by mass or more, there is a tendency that a sufficient curing reaction rate is easily obtained. When the content of component (B) is 40 parts by mass or less, there is a tendency that good heat resistance and adhesiveness are easily maintained. The content of component (B) may be 1 to 30 parts by mass, 3 to 20 parts by mass, or 5 to 10 parts by mass per 100 parts by mass of component (A).

### [Component (C): Thermoplastic Resin]

Component (C) contributes to improvement of film formability of the adhesive. Examples of component (C) include polyester resins, polyether resins, polyamide resins, polyamide-imide resins, polyimide resins, polyvinyl butyral resins, polyvinyl formal resins, phenoxy resins, polyhydroxy polyether resins, acrylic resins, polystyrene resins, butadiene resins, acrylonitrile-butadiene copolymers, acrylonitrile-butadiene-styrene resins, styrene-butadiene copolymers, and acrylic acid copolymers. Among these, from the viewpoint of excellent heat resistance and mechanical strength, component (C) may include a polyimide resin or a phenoxy resin.

The weight-average molecular weight of component (C) may be 10,000 to 800,000, 15,000 to 500,000, or 20,000 to 200,000. When the weight-average molecular weight is within such a range, not only are strength and flexibility favorable when the adhesive is formed into a film, but also the flowability of the adhesive becomes favorable, with a tendency to obtain excellent circuit filling properties (embedability). In the present specification, the weight-average molecular weight means a value measured by gel permeation chromatography and converted using a standard polystyrene calibration curve.

The glass transition temperature of component (C) may be 20° C. to 170° C. or 25° C. to 120° C. When the glass transition temperature of component (C) is 20° C. or higher, the adhesive tends to maintain a film state at room temperature (25° C.). When the glass transition temperature of component (C) is 170° C. or lower, there is a tendency to obtain more excellent connection reliability.

The content of component (C) may be 5 to 60 parts by mass, 10 to 50 parts by mass, 15 to 40 parts by mass, or 20 to 30 parts by mass per 100 parts by mass in total of component (A) and component (C). When the content of component (C) is within such a range, the adhesive tends to be more excellent in film formability and tends to be more excellent in flowability and resin exclusion during thermocompression bonding.

### [Component (D): Non-Conductive Filler]

Component (D) is used, for example, to adjust a coefficient of linear expansion and a modulus of elasticity of the adhesive to desired ranges and to adjust flowability during thermocompression bonding, a modulus of elasticity after thermocompression bonding, and the like.

Component (D) may be an inorganic filler or an organic filler.

Examples of the inorganic filler include metal oxide particles such as silica particles, alumina particles, silica-alumina particles, titania particles, and zirconia particles; and metal nitride particles. These may be used alone as a single kind or in combination of two or more kinds.

Examples of the organic filler include silicone particles, methacrylate-butadiene-styrene particles, acrylic-silicone particles, polyamide particles, and polyimide particles. These may be used alone as a single kind or in combination of two or more kinds.

From the viewpoint of improving film formability of the adhesive and reliability of the connection structure, component (D) may be an inorganic filler. This effect tends to be obtained remarkably when the inorganic filler is silica particles. The silica particles may be crystalline silica particles or non-crystalline silica particles. These silica particles may be synthetic. The method of synthesizing the silica particles may be a dry method or a wet method. The silica particles may include at least one selected from the group consisting of fumed silica particles and sol-gel silica particles.

From the viewpoint of excellent dispersibility in the adhesive, the silica particles may be surface-treated silica particles. The surface-treated silica particles may be, for example, silica particles whose surfaces are treated with a silane compound such as an alkoxysilane compound, a disilazane compound, or a siloxane compound, or may be silica particles whose surfaces are treated with a silane coupling agent. The surface-treated silica particles are, for example, those whose surface hydroxyl groups of the silica particles are rendered hydrophobic by a silane compound or a silane coupling agent.

The average particle diameter of component (D) may be 7 nm to 20 μm. Here, the average particle diameter of component (D) is an average primary particle diameter measured with a flow-type particle image analyzer (for example, FPIA-3000S manufactured by Sysmex Corporation).

The content of component (D) may be 10 to 80 mass %, 15 to 70 mass %, or 20 to 60 mass % based on the total mass of the adhesive components. When the content of component (D) is 10 mass % or more, an increase in the coefficient of linear expansion of the adhesive and a decrease in the modulus of elasticity are suppressed, and excellent connection reliability is easily obtained. When the content of component (D) is 80 mass % or less, the melt viscosity of the adhesive does not become excessively high, with a tendency that the occurrence of voids is further suppressed.

### [Component (E): Organic Acid Component]

Component (E) functions as a fluxing agent. That is, component (E) has a melting point lower than the melting point of the solder connection material and, after melting, removes oxides on the surface of the solder connection material and on metal surfaces such as electrodes, thereby improving solder wettability.

As component (E), organic acids and organic acid esters known as fluxing agents can be used. Examples of the organic acid include succinic acid, glutaric acid, adipic acid, pimelic acid, suberic acid, malic acid, propionic acid, and dimethylol propionic acid. Examples of the organic acid ester include succinic diesters, glutaric diesters, adipic diesters, pimelic diesters, suberic diesters, malic diesters, phthalic diesters, isophthalic diesters, and terephthalic diesters.

The content of component (E) may be 0.1 to 20 mass % or 0.5 to 10 mass % based on the total mass of the adhesive components. When the content of component (E) is within this range, good solder wettability is easily ensured.

### [Component (F): Solder Connection Material]

Component (F) is a connection material containing solder. Component (F) may include at least one solder selected from the group consisting of tin, tin alloys, indium, and indium alloys. When component (F) contains these solder components, diffusion of the solder connection material into electrodes easily occurs, and therefore the effect of the present disclosure (effect of suppressing voids) tends to be obtained remarkably.

Examples of the tin alloy include In—Sn alloys, In—Sn—Ag alloys, Sn—Au alloys, Sn—Bi alloys, Sn—Bi—Ag alloys, Sn—Ag—Cu alloys, and Sn—Cu alloys. Specific examples of these tin alloys are as follows.
In—Sn (In 52 mass %, Sn 48 mass %, melting point 118° C.)
In—Sn—Ag (In 20 mass %, Sn 77.2 mass %, Ag 2.8 mass %, melting point 175° C.)
Sn—Bi (Sn 43 mass %, Bi 57 mass %, melting point 138° C.)
Sn—Bi (Sn 42 mass %, Bi 58 mass %, melting point 138° C.)
Sn—Bi (Sn 72 mass %, Bi 28 mass %, melting point 138° C.)
Sn—Bi—Ag (Sn 42 mass %, Bi 57 mass %, Ag 1 mass %, melting point 139° C.)
Sn—Ag—Cu (Sn 96.5 mass %, Ag 3 mass %, Cu 0.5 mass %, melting point 217° C.)
Sn—Cu (Sn 99.3 mass %, Cu 0.7 mass %, melting point 227° C.)
Sn—Au (Sn 21.0 mass %, Au 79.0 mass %, melting point 278° C.)

Examples of the indium alloy include In—Bi alloys and In—Ag alloys. Specific examples of these indium alloys are as follows.
In—Bi (In 66.3 mass %, Bi 33.7 mass %, melting point 72° C.)
In—Bi (In 33.0 mass %, Bi 67.0 mass %, melting point 109° C.)
In—Ag (In 97.0 mass %, Ag 3.0 mass %, melting point 145° C.)

Note that indium alloys containing tin as described above are classified as tin alloys.

Among the above, when the solder connection material used as component (F) includes at least one selected from the group consisting of Sn—Bi alloys and indium, the effect of the present disclosure (effect of suppressing voids) tends to be obtained more remarkably.

The content of solder in component (F) (for example, the total amount of tin, tin alloys, indium, and indium alloys) may be 90 mass % or more, may be 95 mass % or more, and may also be 99 mass % or more. The solder connection material may consist only of solder, excluding unavoidable impurities.

Component (F) is, for example, solder particles. From the viewpoint of excellent dispersibility and conductivity, the average particle diameter of component (F) may be 1.0 μm or more, 2.0 μm or more, 2.5 μm or more, or 5.0 μm or more. From the viewpoint of ensuring insulation between adjacent electrodes, the average particle diameter of component (F) may be 30.0 μm or less, 25.0 μm or less, 20.0 μm or less, 15.0 μm or less, 10.0 μm or less, 8.0 μm or less, or 5.0 μm or less. From these viewpoints, the average particle diameter of component (F) may be 1.0 to 30.0 μm, 2.0 to 20.0 μm, 2.5 to 20.0 μm, or 5.0 to 20.0 μm. The average particle diameter of component (F) is an average value of particle diameters obtained by measuring particle diameters through observation using a scanning electron microscope (SEM) for 300 solder particles contained in the adhesive. When the solder particles are not spherical, the particle diameter of a solder particle is defined as the diameter of a circle circumscribing the solder particle in an observation image by SEM.

From the viewpoint of obtaining more excellent connection resistance, the content of component (F) may be 3 mass % or more, 5 mass % or more, or 8 mass % or more based on the total mass of the adhesive. From the viewpoint of ensuring insulation between adjacent electrodes, the content of component (F) may be 30 mass % or less, 20 mass % or less, or 15 mass % or less based on the total mass of the adhesive. From these viewpoints, the content of component (F) may be 3 to 30 mass %, 5 to 20 mass %, or 8 to 15 mass % based on the total mass of the adhesive. The content of component (F) may be 0 mass %. In this case, the solder connection material may be, for example, solder bumps disposed on an electrode possessed by at least one of the pair of circuit members. Also when the solder connection material is solder bumps, preferred modes (such as types of solder, solder content, melting point, and the like) of the solder connection material are the same as described above.

From the viewpoint of further suppressing the occurrence of voids, the difference (Tc−Tm) between the curing temperature Tc of the adhesive and the melting point Tm of the solder connection material is preferably −15° C. or more, more preferably −10° C. or more, and may be 0° C. or more, 10° C. or more, or 20° C. or more. The difference (Tc−Tm) may be, for example, 50° C. or less, 40° C. or less, or 30° C. or less, and may be −20° C. to 50° C., −15° C. to 40° C., −10° C. to 30° C., 0° C. to 30° C., 10° C. to 30° C., or 20° C. to 30° C.

The melting point Tm of the solder connection material is, for example, 100° C. or higher, and may be 120° C. or higher, 130° C. or higher, or 140° C. or higher. The melting point Tm of the solder connection material is, for example, 300° C. or lower, and may be 200° C. or lower, 180° C. or lower, 160° C. or lower, or 140° C. or lower. That is, the melting point Tm of the solder connection material is, for example, 100° C. to 300° C., and may also be 120° C. to 200° C., 130° C. to 180° C., 140° C. to 160° C., or 100° C. to 140° C.

From the viewpoint of further suppressing the occurrence of voids, the melt viscosity of the adhesive at the melting point Tm of the solder connection material may be 4.0×10⁵ Pa·s or less, 1.0×10⁵ Pa·s or less, 5.0×10⁴ Pa·s or less, 1.0×10⁴ Pa·s or less, or 5.0×10³ Pa·s or less. The lower limit of the melt viscosity at the melting point Tm of the solder connection material is, for example, 1.0×10³ Pa·s, and may be 1.0×10⁴ Pa·s or 2.0×10⁴ Pa·s. That is, the melt viscosity at the melting point Tm of the solder connection material may be, for example, 1.0×10³ to 5.0×10⁵ Pa·s, and may also be 1.0×10³ to 4.0×10⁵ Pa·s, 1.0×10³ to 1.0×10⁵ Pa·s, 1.0×10³ to 5.0×10⁴ Pa·s, 1.0×10³ to 1.0×10⁴ Pa·s, or 1.0×10³ to 5.0×10³ Pa·s. The melt viscosity of the above-described adhesive can be adjusted, for example, by increasing the curing temperature Tc of the adhesive using the method described above and by the types of thermosetting resin, thermoplastic resin, and non-conductive filler.

In one embodiment, the melt viscosity of the adhesive at 157° C. may be 5.0×10⁵ Pa·s or less. From the viewpoint of further suppressing the occurrence of voids, the melt viscosity of the adhesive at 157° C. is preferably 5.0×10⁵ Pa·s or less, and may also be 4.0×10⁵ Pa·s or less, 1.0×10⁵ Pa·s or less, 5.0×10⁴ Pa·s or less, 1.0×10⁴ Pa·s or less, or 5.0×10³ Pa·s or less. The lower limit of the melt viscosity at 157° C. is, for example, 1.0×10³ Pa·s, and may be 1.0×10⁴ Pa·s or 2.0×10⁴ Pa·s. That is, the melt viscosity at 157° C. may be, for example, 1.0×10³ to 5.0×10⁵ Pa·s, and may also be 1.0×10³ to 4.0×10⁵ Pa·s, 1.0×10³ to 1.0×10⁵ Pa·s, 1.0×10³ to 5.0×10⁴ Pa·s, 1.0×10³ to 1.0×10⁴ Pa·s, or 1.0×10³ to 5.0×10³ Pa·s.

In one embodiment, the melt viscosity of the adhesive at 138° C. may be 5.0×10⁵ Pa·s or less. From the viewpoint of further suppressing the occurrence of voids, the melt viscosity of the adhesive at 138° C. is preferably 5.0×10⁵ Pa·s or less, and may also be 4.0×10⁵ Pa·s or less, 1.0×10⁵ Pa·s or less, 5.0×10⁴ Pa·s or less, 1.0×10⁴ Pa·s or less, or 5.0×10³ Pa·s or less. The lower limit of the melt viscosity at 138° C. is, for example, 1.0×10³ Pa·s, and may be 1.0×10⁴ Pa·s or 2.0×10⁴ Pa·s. That is, the melt viscosity at 138° C. may be, for example, 1.0×10³ to 5.0×10⁵ Pa·s, and may also be 1.0×10³ to 4.0×10⁵ Pa·s, 1.0×10³ to 1.0×10⁵ Pa·s, 1.0×10³ to 5.0×10⁴ Pa·s, 1.0×10³ to 1.0×10⁴ Pa·s, or 1.0×10³ to 5.0×10³ Pa·s.

From the viewpoint of further suppressing the occurrence of voids, the difference (Tc−Tp) between the curing temperature Tc of the adhesive and a thermocompression bonding temperature Tp may be −30° C. to 120° C., and may also be −25° C. to 60° C. or −20° C. to 30° C.

From the viewpoint of excellent handling properties, the adhesive is preferably in the form of a film (that is, an adhesive film). The thickness of the film may be, for example, 5 μm or more or 10 μm or more, and may be 40 μm or less, 30 μm or less, or 20 μm or less.

The adhesive film can be prepared, for example, by the following method. First, the above-described components are dissolved or dispersed by stirring and mixing in an organic solvent to prepare a varnish (a varnish-like adhesive). Next, the obtained varnish is applied onto a base material subjected to a release treatment using a knife coater, a roll coater, an applicator, a comma coater, a die coater, or the like to form a coating film. Next, the organic solvent in the coating film is volatilized by heating. Thus, an adhesive film can be formed on the base material. At this time, by adjusting the application amount of the varnish, the thickness of the adhesive film can be adjusted.

The organic solvent used in preparation of the varnish is not particularly limited as long as it has characteristics that allow the components to be dissolved or dispersed substantially uniformly. Examples of such organic solvents include toluene, acetone, methyl ethyl ketone, methyl isobutyl ketone, ethyl acetate, propyl acetate, and butyl acetate. These organic solvents can be used alone or in combination of two or more kinds. Stirring and mixing or kneading during preparation of the varnish can be performed using, for example, a stirrer, a disperser, a three-roll mill, a ball mill, a bead mill, a homodisper, or the like.

The base material is not particularly limited as long as it has heat resistance that can withstand heating conditions during volatilization of the organic solvent. Examples of such a base material include base materials (for example, films) made of oriented polypropylene (OPP), polyethylene terephthalate (PET), polyethylene naphthalate, polyethylene isophthalate, polybutylene terephthalate, polyolefin, polyacetate, polycarbonate, polyphenylene sulfide, polyamide, polyimide, cellulose, ethylene-vinyl acetate copolymers, polyvinyl chloride, polyvinylidene chloride, synthetic rubber, liquid crystal polymers, and the like.

Heating conditions for volatilizing the organic solvent from the varnish applied to the base material can be appropriately set according to the organic solvent used and the like. The heating conditions may be, for example, 40° C. to 120° C. for 0.1 to 10 minutes.

A part of the solvent may remain unremoved in the adhesive. The solvent content in the adhesive may be, for example, 0 to 10 mass % based on the total mass of the adhesive.

The adhesive described above is used when a pair of circuit members is thermocompression bonded via a solder connection material. More specifically, it is used to bond a pair of circuit members in the method for manufacturing a circuit connection structure described below.

### <Method for Manufacturing Circuit Connection Structure>

In a method for manufacturing a circuit connection structure according to one embodiment, when a pair of circuit members is thermocompression bonded via a solder connection material, the adhesive of the above embodiment is interposed between the pair of circuit members. Hereinafter, one of the pair of circuit members is referred to as a first circuit member, and the other is referred to as a second circuit member. Further, an electrode (connection portion) possessed by the first circuit member is referred to as a first electrode, and an electrode (connection portion) possessed by the second circuit member is referred to as a second electrode.

The method for manufacturing a circuit connection structure includes, for example, a step (a) of arranging a pair of circuit members (a first circuit member having a first electrode and a second circuit member having a second electrode) such that the electrodes (the first electrode and the second electrode) face each other, and a step (b) of thermocompression bonding the pair of circuit members (the first circuit member and the second circuit member) arranged to face each other via an adhesive. The solder connection material is, for example, disposed on the electrode of at least one of the pair of circuit members or contained in the adhesive as component (F).

The adhesive is, for example, the adhesive of the above embodiment, wherein the difference (Tc−Tm) between a curing temperature Tc of the adhesive and a melting point Tm of the solder connection material is −20° C. or more, and the melt viscosity of the adhesive at the melting point Tm of the solder connection material is 5.0×10⁵ Pa·s or less.

According to this method, since the first circuit member and the second circuit member are thermocompression bonded in a state where the solder connection material is interposed between the first electrode and the second electrode, the first electrode and the second electrode are electrically connected by solder bonding. Then, since the adhesive of the above embodiment is used to bond the first circuit member and the second circuit member to each other, the occurrence of voids near the solder connection portions, that is, in the vicinity of the first electrode and the second electrode solder-bonded to each other, is suppressed.

The circuit members (the first circuit member and the second circuit member) may be circuit substrates, or may be semiconductor wafers or semiconductor chips. Examples of the circuit substrate include a glass substrate or a plastic substrate (a plastic substrate made of an organic material such as polyimide, polycarbonate, polyethylene terephthalate, or cycloolefin polymer) on which circuit electrodes are formed; printed wiring boards; ceramic wiring boards; and flexible wiring boards. Examples of the semiconductor chip include driver IC chips and micro-LED chips. The combination of the first circuit member and the second circuit member is not particularly limited. The first circuit member and the second circuit member may be the same as or different from each other. For example, both the first circuit member and the second circuit member may be semiconductor chips, or one may be a circuit substrate or a semiconductor wafer and the other may be a semiconductor chip.

The electrodes (the first electrode and the second electrode) are formed on substrates constituting the circuit members. The electrodes may be electrodes containing metals such as gold, silver, tin, ruthenium, rhodium, palladium, osmium, iridium, platinum, copper, aluminum, molybdenum, titanium, and nickel, oxides such as indium tin oxide (ITO), indium zinc oxide (IZO), and indium gallium zinc oxide (IGZO), and the like. The electrodes may be electrodes formed by laminating layers composed of these metals and oxides. In this case, the electrodes may have a two-layer structure or a structure of three or more layers.

It is preferable that at least one of the pair of circuit members have, as the electrode, an electrode including copper, gold, or a gold alloy on a surface in contact with the solder connection material. In this case, since diffusion of the solder connection material into the electrode tends to occur, the effect of the present disclosure (effect of suppressing voids) tends to be obtained remarkably. As described above, diffusion of the solder connection material into the electrode particularly tends to occur when the solder connection material contains at least one selected from the group consisting of tin, tin alloys, indium, and indium alloys. Therefore, when at least one of the pair of circuit members has, on a surface in contact with the solder connection material, an electrode including copper, gold, or a gold alloy, and the solder connection material contains at least one selected from the group consisting of tin, tin alloys, indium, and indium alloys, the effect of the present disclosure tends to be obtained more remarkably. The electrode including copper, gold, or a gold alloy on a surface in contact with the solder connection material may be an electrode formed of copper, gold, or a gold alloy, or may be an electrode including a plating layer formed of copper, gold, or a gold alloy.

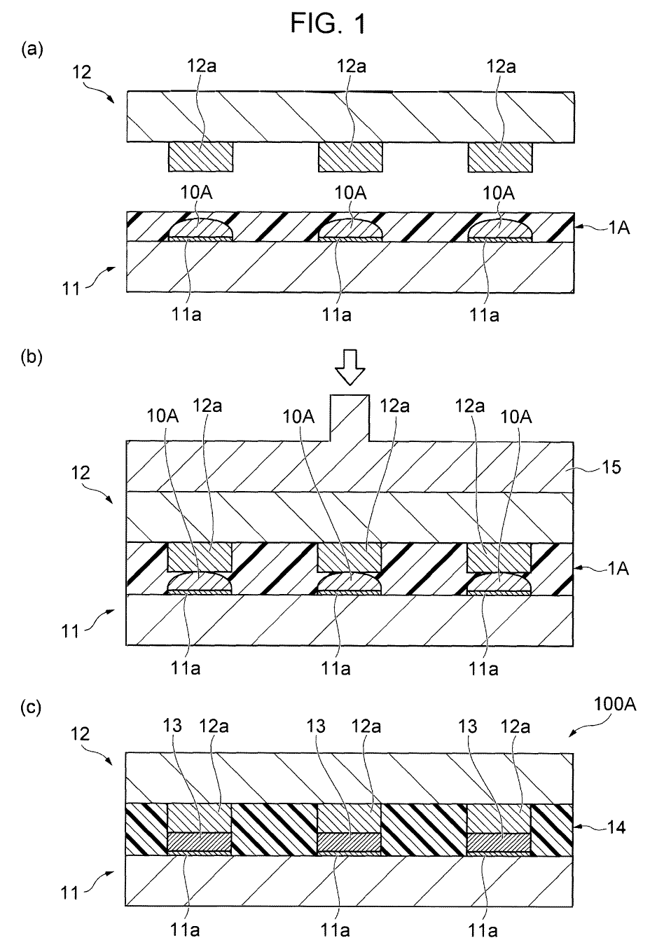

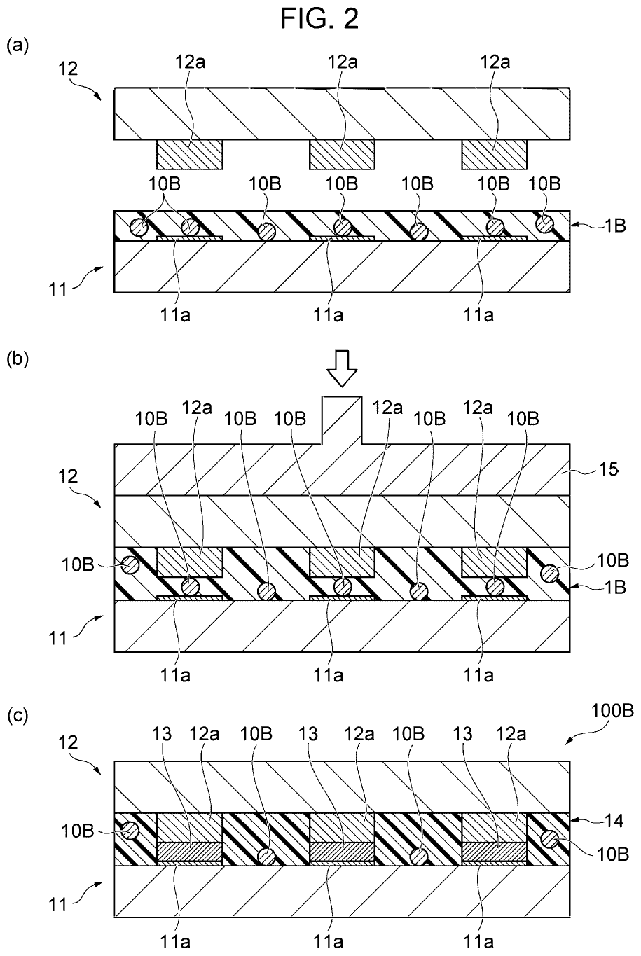

Next, the method for manufacturing a circuit connection structure of the above embodiment will be described in more detail with reference to FIG. 1 and FIG. 2.

FIG. 1 is a schematic cross-sectional view illustrating a method for manufacturing a circuit connection structure 100A using an adhesive that does not contain a solder connection material. FIG. 2 is a schematic cross-sectional view illustrating a method for manufacturing a circuit connection structure 100B using an adhesive that contains a solder connection material. In the method of FIG. 1, solder bumps 10A are used as the solder connection material, and as the adhesive, an adhesive 1A that does not contain the solder connection material is used. In the method of FIG. 2, solder particles 10B are used as the solder connection material, and as the adhesive, an adhesive 1B containing the solder connection material (solder particles) is used.

In the step (a), for example, first, using the adhesive 1A or the adhesive 1B, a layer composed of the adhesive is formed on a first circuit member 11 (on a surface on which a first electrode 11a is formed). Next, a second circuit member 12 is disposed on the first circuit member 11 such that the first electrode 11a and a second electrode 12a face each other (see FIG. 1(a) and FIG. 2(a)).

The method for forming a layer composed of the adhesive on the first circuit member 11 may be, for example, a method using a liquid adhesive, or a method using a film-like adhesive (adhesive film). When a liquid adhesive is used, a layer composed of the adhesive can be formed in the same manner as the above-described method for producing an adhesive film. Examples of the method using an adhesive film include heat pressing, roll lamination, and vacuum lamination. Lamination can be performed, for example, under temperature conditions of 0° C. to 80° C.

Since alignment is required when the second circuit member 12 is disposed on the first circuit member 11, in general, a bonding machine such as a flip-chip bonder is used. Although not illustrated, in the step (a), heating and pressing may be performed when the second circuit member 12 is disposed on the first circuit member 11. This step is generally called provisional bonding, and when provisional bonding is performed, thermocompression bonding in the step (b) is called main bonding. Provisional bonding may be performed using a heating and pressing tool (bonding head) of the bonding machine. The heating temperature at the time of provisional bonding (provisional bonding temperature) is adjusted such that a maximum attained temperature (for example, a maximum attained temperature of the adhesive) is lower than the melting point Tm of the solder connection material and lower than the curing temperature Tc of the adhesive, so that the solder connection material does not melt and the adhesive does not lose heat-induced flowability. When the first circuit member is disposed on a heatable stage, provisional bonding may be performed while heating the stage.

In the step (b), the first circuit member 11 and the second circuit member 12 are thermocompression bonded via the adhesive 1A or the adhesive 1B. Thermocompression bonding can be performed using a heating and pressing tool 15 as illustrated in FIG. 2 (b). Specifically, the first circuit member 11 and the second circuit member 12 are thermocompression bonded by heating while pressing the second circuit member 12 against the first circuit member 11 (in the direction indicated by the arrow in FIG. 2(b)) using the heating and pressing tool 15.

During thermocompression bonding, in the method of FIG. 1, the solder bumps 10A are interposed between the first electrode 11a and the second electrode 12a, and in the method of FIG. 2, the solder particles 10B are interposed between the first electrode 11a and the second electrode 12a. These solder connection materials (the solder bumps 10A or the solder particles 10B) melt as a result of the thermocompression bonding (heating and pressing) and solidify upon cooling to form a solder connection portion 13 between the first electrode 11a and the second electrode 12a. As a result, the first electrode 11a and the second electrode 12a are electrically connected. In addition, the adhesive components in the adhesive cure as a result of the above heating, and an underfill 14 is formed in a gap between the first circuit member 11 and the second circuit member 12. In this way, the first circuit member 11 and the second circuit member 12 are bonded (fixed) to each other, the solder connection portion 13 is sealed, and a circuit connection structure (100A or 100B) is obtained (see FIGS. 1(b) and 1(c), and FIGS. 2(b) and 2 (c)).

The thermocompression bonding temperature Tp is higher than the melting point Tm of the solder connection material and is, for example, 130° C. to 240° C. From the viewpoint of curability of the adhesive, the thermocompression bonding temperature Tp is preferably 140° C. or higher, and more preferably 150° C. or higher. From the viewpoint of solder melting after thermocompression bonding, the thermocompression bonding temperature Tp is preferably 200° C. or lower, and more preferably 190° C. or lower. Here, the thermocompression bonding temperature Tp is a maximum attained temperature during thermocompression bonding and is determined, for example, by the maximum attained temperature of the adhesive.

Thermocompression bonding may be performed by pressing a heating and pressing tool heated to a temperature near the thermocompression bonding temperature Tp (for example, [Tp−10]° C. to Tp° C.) against the circuit members, or by pressing a heating and pressing tool that is unheated or heated to a temperature sufficiently lower than the thermocompression bonding temperature Tp (for example, a temperature lower than the melting point Tm of the solder connection material) against the circuit members. That is, the heating start temperature in thermocompression bonding may be [Tp−10]° C. to Tp° C., or may be a temperature lower than the melting point Tm of the solder connection material.

When a heating and pressing tool that is unheated or heated to a temperature sufficiently lower than the thermocompression bonding temperature Tp is used, the heating start temperature (for example, the temperature of the heating and pressing tool 15 at the start of pressing) may be 20° C. to 100° C., and the temperature ramp rate may be 7° C. to 11° C./min.

When a heating and pressing tool heated to a temperature near the thermocompression bonding temperature Tp is used, the thermocompression bonding time (time from the start of heating to the end of heating) is preferably 180 seconds or less (for example, 5 to 160 seconds) from the viewpoint of further suppressing the occurrence of voids, more preferably 5 to 160 seconds, even more preferably 5 to 140 seconds, and particularly preferably 5 to 120 seconds. When a heating and pressing tool that is unheated or heated to a temperature sufficiently lower than the thermocompression bonding temperature Tp is used, the thermocompression bonding time is preferably 15 minutes or less (for example, 0.1 to 15 minutes) from the viewpoint of further suppressing the occurrence of voids, more preferably 0.1 to 13 minutes, and even more preferably 0.1 to 10 minutes.

When the first circuit member is disposed on a heatable stage, thermocompression bonding may be performed while heating the stage, but it is preferable that the heating temperature of the stage be lower than the melting point Tm of the solder connection material.

The pressure during thermocompression bonding is appropriately set according to, for example, the size and number of the circuit members to be connected. The pressure may be, for example, higher than atmospheric pressure and 1 MPa or less. From the viewpoint of improving connectivity, a high pressure is preferable; whereas from the viewpoint of suppressing fillets, a lower pressure is preferable. The pressure may be, for example, 0.1 to 100 MPa.

Cooling after thermocompression bonding may be performed by natural cooling (for example, 20° C. to 30° C.).

While the method for manufacturing a circuit connection structure according to the embodiment has been described with reference to the methods of FIG. 1 and FIG. 2 as examples, the method for manufacturing a circuit connection structure is not limited to the above examples.

For example, in the step (a), a layer composed of the adhesive may be formed on the second circuit member. However, from the viewpoint of thermocompression bonding, it is preferable to form the layer composed of the adhesive on a circuit member on which solder bumps are formed. This is because the thermocompression bonding tool is often applied with 12 turned over, which promotes curing of the layer composed of the adhesive. In the step (b), the first circuit member and the second circuit member may be thermocompression bonded by heating while pressing the first circuit member against the second circuit member using the heating and pressing tool.

In FIG. 1 and FIG. 2, the number of the first circuit member and the number of the second circuit member are each one, but neither the number of the first circuit member nor the number of the second circuit member is limited to one. For example, a mode in which a plurality of semiconductor chips are collectively mounted on a large-area circuit substrate is also encompassed by the method of this embodiment.

When a plurality of semiconductor chips are collectively mounted on a circuit substrate, it is preferable to perform thermocompression bonding by pressing a heating and pressing tool that is unheated or heated to a temperature sufficiently lower than the thermocompression bonding temperature Tp against the circuit members in order to cure the adhesive uniformly. In this method, the heating time tends to become long, and in related art methods the amount of void occurrence tends to increase remarkably; however, according to the method of this embodiment, the occurrence of voids can be suppressed.

### EXAMPLES

Hereinafter, the present disclosure will be described in detail by way of examples. However, the present disclosure is not limited to the examples below.

### <Preparation of Materials>

As materials used in the following examples, the materials shown below were prepared. Note that the gel times of AB-2 to AB-4 each mean a gel time of a microencapsulated imidazole-based curing agent alone. Further, C-1 was used after dilution with a solvent (a mixed solvent of toluene and ethyl acetate (ratio 1:1)) so that the solids concentration became 40 mass %.

### (Thermosetting Components)

AB-1: HXA4982HP (trade name, Asahi Kasei Corporation; thermosetting mixture containing 60 to 70 mass % epoxy resin and 30 to 40 mass % microencapsulated imidazole-based curing agent (capsule membrane thickness: extra thick))
AB-2: HXA9382HP (trade name, Asahi Kasei Corporation; thermosetting mixture containing 60 to 70 mass % epoxy resin and 30 to 40 mass % microencapsulated imidazole-based curing agent (capsule membrane thickness: extra thick, gel time at 100° C.: >30 min))
AB-3: HXA3042HP (trade name, Asahi Kasei Corporation; thermosetting mixture containing 60 to 70 mass % epoxy resin and 30 to 40 mass % microencapsulated imidazole-based curing agent (capsule membrane thickness: thick, gel time at 100° C.: 2.0 min))
AB-4: HXA3941HP (trade name, Asahi Kasei Corporation; thermosetting mixture containing 60 to 70 mass % epoxy resin and 30 to 40 mass % microencapsulated imidazole-based curing agent (capsule membrane thickness: extra thick, gel time at 100° C.: 2.5 min))
A-1: jER1032H60 (trade name (“jER” is a registered trademark), Mitsubishi Chemical Corporation; multifunctional solid epoxy containing a triphenylmethane skeleton)
A-2: HTR-P3-TEA (trade name, Nagase ChemteX Corporation; copolymer of butyl acrylate/ethyl acrylate/acrylonitrile/glycidyl methacrylate (mass ratio 40/30/30/3), Mw 850,000)

### (Thermoplastic Resins)

C-1: FX293 (trade name, Nippon Steel Chemical & Material Co., Ltd.; biphenyl-fluorene-type phenoxy resin; weight-average molecular weight: 45,000; glass transition temperature: 158° C.)
C-2: PKHC (phenoxy resin, Union Carbide Corporation)

### (Non-Conductive Filler)

D-1: R805 (Evonik Industries AG; hydrolysis product (silica fine particles) of trimethoxyoctylsilane and silica; a solution diluted with an organic solvent to a non-volatile content of 10 mass % was used)

### (Organic Acid Component)

E-1: Dimethyl glutarate (Tokyo Chemical Industry Co., Ltd.)

### (Solder Particles)

F-1: In powder (trade name, Fujifilm Wako Pure Chemical Corporation; average particle diameter: 50 μm; melting point: 157° C.)
F-2: Sn42Bi58 solder particles (Sn42Bi58 Type 5, Mitsui Kinzoku Co., Ltd.; particles having a particle diameter of 15 to 25 μm account for 80% or more of the total; melting point: 138° C.)

### Examples 1a to 5a and Comparative Example 1a

### (Production of Adhesive Films)

After mixing the materials shown in Table 1 with an organic solvent, the resulting mixture (a varnish-like adhesive) was applied onto a PET (polyethylene terephthalate) film subjected to a release treatment. As the organic solvent, a mixed solvent of toluene and ethyl acetate was used. The materials shown in Table 1 were blended in the blending amounts shown in Table 1 (on a non-volatile basis, unit: parts by mass). Coating was performed such that the thickness of a film-like adhesive (adhesive film) obtained after drying became 30 μm. Then, by removing the organic solvent by drying, adhesive films of Examples 1a to 5a and Comparative Example 1a were obtained.

### (Dsc Measurement)

DSC measurement of the adhesive films obtained above was performed under the conditions below, and a curing temperature Tc of each adhesive film and a transition initiation temperature (onset temperature) of an exothermic peak indicating the curing temperature Tc were determined. The results are shown in Table 1.

### [Conditions]

Apparatus: Differential scanning calorimeter (DSC2500, TA Instruments)
Measurement atmosphere: Helium atmosphere (flow rate: 25 ml/min)
Measurement temperature range: 40° C. to 300° C.
Temperature ramp rate: 10° C./min

### (Preparation of Connection Structures)

Using the adhesive films of Examples 1a to 5a and Comparative Example 1a obtained above, circuit connection structures of Examples 1a to 5a and Comparative Example 1a were prepared, respectively.

Specifically, first, as circuit members, a PWB (with Cu, Ni, and Au plating) (circuit member A) and an FPC (with Cu, Ni, and Au plating) (circuit member B) were prepared. Next, solder bumps serving as a solder connection material were formed on an electrode of the circuit member A to obtain a circuit member with solder bumps. In this step, in Examples 1a to 4a and Comparative Example 1a, In solder (melting point 157° C.) was used as solder bumps (solder connection material), and the thickness of the solder bumps was set to 25 μm. In Example 5a, Sn—Bi solder (Sn 72 mass %, Bi 28 mass %, melting point 138° C.) was used as solder bumps (solder connection material), and the thickness of the solder bumps was set to 15 μm.

Using the circuit member with solder bumps as a first circuit member and the circuit member B as a second circuit member, a connection structure was prepared. Specifically, after disposing the adhesive film on the electrode side of the circuit member with solder bumps, the circuit member with solder bumps and the circuit member B were aligned so that their electrodes faced each other. Next, the circuit member with solder bumps and the second circuit member B arranged to face each other were thermocompression bonded using a heating and pressing tool to obtain a circuit connection structure. The thermocompression bonding conditions of each example are as follows.

### Thermocompression Bonding Conditions for Examples 1a to 4a and Comparative Example 1a

Heating start temperature: 40° C.
Temperature ramp rate: 14° C./min
Thermocompression bonding temperature Tp (maximum attained temperature of adhesive): as shown in Table 1
Thermocompression bonding time (time from start of heating to end of heating): 10 min
Pressure: 25 MPa
   [Thermocompression Bonding Conditions for Example 5a]
Heating start temperature: 40° C.
Temperature ramp rate: 13.75° C./s
Thermocompression bonding temperature Tp (maximum attained temperature of adhesive): as shown in Table 1
Thermocompression bonding time (time from start of heating to end of heating): 8 s
Pressure: 1 MPa

### (Void Evaluation)

The presence or absence of voids in the vicinity of the solder connection portions of the prepared circuit connection structures was evaluated by the following method. The results are shown in Table 1.
A: No voids are present in a cross-sectional area of solder
B: Void area is more than 0% and 5% or less relative to a cross-sectional area of solder
C: Void area is more than 5% and less than 20% relative to a cross-sectional area of solder
D: Void area is 20% or more relative to a cross-sectional area of solder

### Examples 1b to 5b and Comparative Example 1b

After mixing the materials shown in Table 2 with an organic solvent, the resulting mixture (a varnish-like adhesive) was applied onto a PET (polyethylene terephthalate) film subjected to a release treatment. As the organic solvent, a mixed solvent of toluene and ethyl acetate was used. The materials shown in Table 2 were blended in the blending amounts shown in Table 2 (on a non-volatile basis, unit: parts by mass). Coating was performed such that the thickness of a film-like adhesive (adhesive film) obtained after drying became 30 μm. Then, by removing the organic solvent by drying, adhesive films (1b to 6b) of Examples 1b to 5b and Comparative Example 1b were obtained.

### (Preparation of Connection Structures)

As circuit members, a PWB (with Cu, Ni, and Au plating) (circuit member A) and an FPC (with Cu, Ni, and Au plating) (circuit member B) were prepared. Next, except that the adhesive films of Examples 1b to 5b and Comparative Example 1b obtained above were used as the adhesive films and the thermocompression bonding conditions were changed as shown below, circuit connection structures of Examples 1b to 5b and Comparative Example 1b were prepared in the same manner as in Examples 1a to 5a and Comparative Example 1a, and void evaluation of the circuit connection structures was performed. The results are shown in Table 2.

### Thermocompression Bonding Conditions for Examples 1b to 4b and Comparative Example 1b

Heating start temperature: 40° C.
Temperature ramp rate: 14° C./min
Thermocompression bonding temperature Tp (maximum attained temperature of adhesive): as shown in Table 2
Thermocompression bonding time (time from start of heating to end of heating): 10 min
Pressure: 25 MPa

### Thermocompression Bonding Conditions for Example 5b

Heating start temperature: 40° C.
Temperature ramp rate: 3.67° C./s
Thermocompression bonding temperature Tp (maximum attained temperature of adhesive): as shown in Table 2
Thermocompression bonding time (time from start of heating to end of heating): 30 s
Pressure: 1 MPa

TABLE 1

| | | Example | Example | Example | Example | Example | Comparative |
|---|---|---|---|---|---|---|---|
| | | 1a | 2a | 3a | 4a | 5a | Example 1a |
| Thermosetting | AB-1 | 60.0 | — | 51.5 | — | — | — |
| component | AB-2 | — | 60.0 | — | 51.5 | — | — |
| | AB-3 | — | — | — | — | 51.5 | — |
| | AB-4 | — | — | — | — | — | 60.0 |
| | A-1 | 20.0 | 20.0 | — | — | — | 20.0 |
| | A-2 | — | — | 36 | 36 | 36 | — |
| Thermoplastic | C-1 | 20.0 | 20.0 | — | — | — | 20.0 |
| resin | C-2 | — | — | 12.5 | 12.5 | 12.5 | — |
| Non-conductive | D-1 | — | — | — | — | — | — |
| filler | | | | | | | |
| Organic acid | E-1 | 3.0 | 3.0 | — | — | — | 3.0 |
| component | | | | | | | |

| | | | | | | |
|---|---|---|---|---|---|---|
| Curing temperature | 181 | 183 | 181 | 183 | 135 | 121 |
| Tc (° C.) | | | | | | |
| Onset temperature | 159 | 158 | 159 | 158 | 105 | 91 |
| (° C.) | | | | | | |
| Melting point | 157 | 157 | 157 | 157 | 138 | 157 |
| Tm (° C.) | | | | | | |
| Tc − Tm (° C.) | 23.97 | 26.13 | 23.97 | 26.13 | −3.3 | −36.12 |
| Melt viscosity | 2.2.E+04 | 3.9.E+03 | 2.2.E+04 | 4.0.E+03 | 8.0.E+04 | 6.3.E+05 |
| (Pa · s) | | | | | | |
| Thermocompression | 180 | 180 | 180 | 180 | 150 | 180 |
| bonding temperature | | | | | | |
| Tp (° C.) | | | | | | |
| Tc − Tp (° C.) | 1 | 3 | 1 | 3 | −15 | −59 |
| Void evaluation | B | A | B | A | B | D |

TABLE 2

| | | Example | Example | Example | Example | Example | Comparative |
|---|---|---|---|---|---|---|---|
| | | 1b | 2b | 3b | 4b | 5b | Example 1b |
| Thermosetting | AB-1 | 60.0 | — | 51.5 | — | — | — |
| component | AB-2 | — | 60.0 | — | 51.5 | — | — |
| | AB-3 | — | — | — | — | 51.5 | — |
| | AB-4 | — | — | — | — | — | 60.0 |
| | A-1 | 20.0 | 20.0 | — | — | — | 20.0 |
| | A-2 | — | — | 36 | 36 | 36 | — |
| Thermoplastic | C-1 | 20.0 | 20.0 | — | — | — | 20.0 |
| resin | C-2 | — | — | 12.5 | 12.5 | 12.5 | — |
| Non-conductive | D-1 | 8.0 | 8.0 | — | — | — | 8.0 |
| filler | | | | | | | |
| Organic acid | E-1 | 3.0 | 3.0 | — | — | — | 3.0 |
| component | | | | | | | |
| Solder particles | F-1 | 38.8 | 38.8 | 35.0 | 35.0 | — | 38.8 |
| | F-2 | — | — | — | — | 32.5 | — |

| | | | | | | |
|---|---|---|---|---|---|---|
| Curing temperature | 181 | 183 | 181 | 183 | 135 | 121 |
| Tc (° C.) | | | | | | |
| Onset temperature | 159 | 158 | 159 | 158 | 105 | 91 |
| (° C.) | | | | | | |
| Melting point | 157 | 157 | 157 | 157 | 138 | 157 |
| Tm (° C.) | | | | | | |
| Tc − Tm (° C.) | 23.97 | 26.13 | 23.97 | 26.13 | −3.3 | −36.12 |
| Melt viscosity | 2.2.E+04 | 3.9.E+03 | 2.2.E+04 | 4.0.E+03 | 8.0.E+04 | 6.3.E+05 |
| (Pa · s) | | | | | | |
| Thermocompression | 180 | 180 | 180 | 180 | 150 | 180 |
| bonding temperature | | | | | | |
| Tp (° C.) | | | | | | |
| Tc − Tp (° C.) | 1 | 3 | 1 | 3 | −15 | −59 |
| Void evaluation | B | A | B | A | B | D |

In Tables 1 and 2 above, “Melt viscosity” is a melt viscosity of an adhesive film at the melting point Tm of a solder connection material and is a value measured under the following conditions.

### [Conditions]

Apparatus: Melt viscosity measuring apparatus (ARES-G2, TA Instruments)
Measurement temperature: 0° C. to 200° C.
Temperature ramp rate: 10° C./min
Frequency: 10 Hz
Strain: 1%

### REFERENCE SIGNS LIST

1A, 1B . . . adhesive, 10A . . . solder bump (solder connection material), 10B . . . solder particles (solder connection material), 11 . . . first circuit member, 11a . . . first electrode, 12 . . . second circuit member, 12a . . . second electrode, 13 . . . solder connection portion, 14 . . . underfill, 15 . . . heating and pressing tool, 100A, 100B . . . circuit connection structure.

1. An adhesive that is thermosetting and used in thermocompression bonding of a pair of circuit members via a solder connection material in a method for manufacturing a circuit connection structure including the pair of circuit members electrically connected by solder bonding,
wherein the adhesive has
a curing temperature Tc such that a difference (Tc−Tm) from a melting point Tm of the solder connection material is −20° C. or more, and
a melt viscosity at the melting point Tm of the solder connection material of 5.0×10⁵ Pa·s or less.

2. The adhesive according to claim 1, wherein the curing temperature Tc is 100° C. to 200° C.

3. The adhesive according to claim 1, having a melt viscosity at 157° C. of 5.0×10⁵ Pa·s or less.

4. The adhesive according to claim 1, comprising at least a thermosetting resin and a curing agent for the thermosetting resin,
wherein the thermosetting resin comprises an epoxy resin.

5. The adhesive according to claim 4, wherein the curing agent comprises an imidazole-based curing agent.

6. The adhesive according to claim 4, wherein the curing agent comprises a microencapsulated latent curing agent.

7. The adhesive according to claim 1, wherein the adhesive is insulating.

8. The adhesive according to claim 1, comprising the solder connection material.

9. The adhesive according to claim 1, wherein the adhesive is in the form of a film.

10. The adhesive according to claim 1, wherein at least one of the pair of circuit members has an electrode comprising copper, gold, or a gold alloy on a surface in contact with the solder connection material, and
the solder connection material comprises at least one selected from the group consisting of tin, tin alloys, indium, and indium alloys.

11. A method for manufacturing a circuit connection structure using a solder connection material, comprising:
arranging a pair of circuit members such that electrodes of the pair of circuit members face each other; and
of thermocompression bonding the pair of circuit members arranged to face each other via a thermosetting adhesive,
wherein the solder connection material is disposed on the electrode of at least one of the pair of circuit members, or the adhesive comprises the solder connection material,
a difference (Tc−Tm) between a curing temperature Tc of the adhesive and a melting point Tm of the solder connection material is −20° C. or more, and
a melt viscosity of the adhesive at the melting point Tm of the solder connection material is 5.0×10⁵ Pa·s or less.
